(19) United States
(12) Patent Application Publication
(10) Pub. No.: US 2008/0257408 A1
(43) Pub. Date: Oct. 23, 2008

(54) Solar light concentrator

(75) Inventors: Jyh-Long Chen, Hsinchu City (TW); Meng-Hua Wang, Hsinchu City (TW); Jeng-Cheng Chen, Hsinchu City (TW); Chia-Yu Hu, Hsinchu City (TW); Hwa-Yuh Shin, Lungtan (TW); Hwen-Fen Hong, Lungtan (TW); Hung-Zen Kuo, Lungtan (TW)

Correspondence Address: TROXELL LAW OFFICE PLLC, 5205 LEESBURG PIKE, SUITE 1404, FALLS CHURCH, VA, 22041, US

(73) Assignee: Atomic Energy Council - Institute of Nuclear Energy Research, Taoyuan (TW)

(21) Appl. No.: 11/790,080

(22) Filed: Apr. 23, 2007

(51) Int. Cl. H01L 31/052

(52) U.S. Cl. 136/259

(57) ABSTRACT

A diffusion plate is used in a concentrator for solar light. By the diffusion plate, solar beams is evenly distributed on a solar cell. As a result, the whole solar cell can evenly receives the solar beams for energy transformation.

### FIELD OF THE INVENTION

The present, invention relates to collecting solar light; more particularly relates to curing energy focus at center of a solar cell so as to evenly receiving energy of solar beams by a whole solar cell.

### DESCRIPTION OF THE RELATED ART

Following the development of industries, energies are running out and greenhouse effect is getting worse so that a stable supply of energy has become a major concern to the world. Comparing to traditional energies obtained from burning oil or gas and nuclear energy, a solar cell directly transforms solar energy into electricity through photoelectric effect without accompanying with poisonous material, such as carbon dioxide, nitric oxide, sulfur oxide, etc. The solar cell can thus eliminate the needs in oil and provide safe and self-sufficient power source.

A general solar energy collector uses Fresnel lens on a solar cell to respond to the position changes of the sun for receiving incidence solar light from any direction. The Fresnel lens is well applied to solar cells of big scale with light distributed evenly. Yet, regarding applying it to solar cells of small scale, high energy is gathered at center of the solar cell owing to pitch limited and so the light source is not distributed evenly. In a word, light source is not distributed evenly when applying the Fresnel lens to a small-scale solar cell. Hence, the prior art does not fulfill users' requests on actual use.

### SUMMARY OF THE INVENTION

The main purpose of the present invention is to improve an evenness of distribution of solar beams with a diffusion plate by curing energy focus at center of a solar cell so as to evenly receiving energy of solar beams by a whole solar cell.

To achieve the above purpose, the present invention is a solar light concentrator, comprising a solar cell to collect solar beam energy; a non-plane lens unit deposed on a surface of the solar cell to receive incidence solar light from any direction; and a diffusing zone deposed in an active area of the non-plane lens unit to diffuse solar beams throughout the whole solar cell. Accordingly, a novel solar light concentrator is obtained.

### BRIEF DESCRIPTION OF THE DRAWINGS

The present invention will be better understood from the following detailed descriptions of the preferred embodiments according to the present invention, taken in conjunction with the accompanying drawings, in which

FIG. 1 is the sectional view showing the first preferred embodiment according to the present invention;

FIG. 2 is the view showing the energy amplitude distribution of solar beams on the solar cell;

FIG. 3 is the view showing the state of use of the first preferred embodiment;

FIG. 4 is the view showing the state of use of the second preferred embodiment; and

FIG. 5 is the view showing the state of use of the third preferred embodiment.

### DESCRIPTION OF THE PREFERRED EMBODIMENTS

The following descriptions of the preferred embodiments are provided to understand the features and the structures of the present invention.

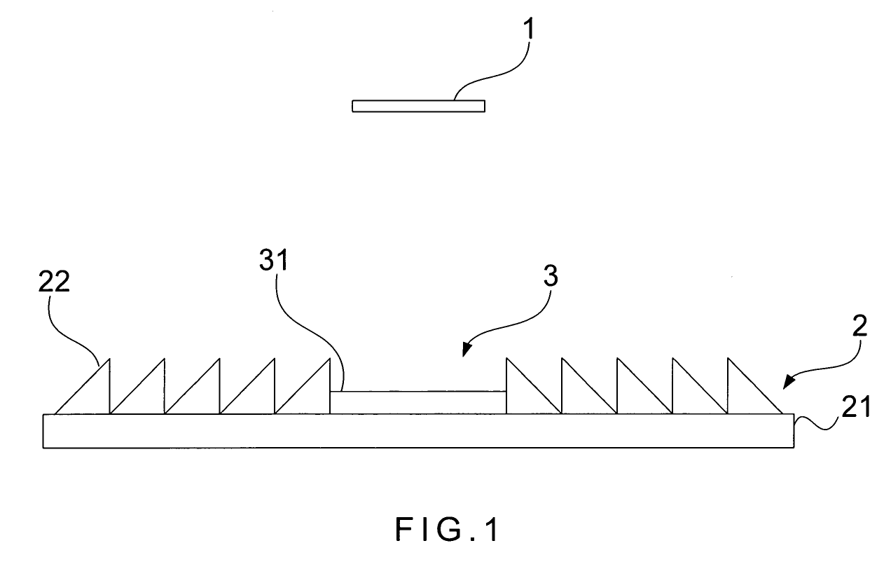

Please refer to FIG. 1, which is a sectional view showing a first preferred embodiment according to the present invention. As shown in the figure, the present invention is a solar light concentrator, comprising a solar cell 1, a non-plane lens unit 2 and a diffusing zone 3, where an evenness for a distribution of solar beams is improved through the diffusing zone 3 to avoid energy focus at center of the solar cell 1 and so the solar cell 1 uniformly receives energy of the solar beams.

The solar cell 1 collects energy of the solar beams.

The non-plane lens unit 2 is set on a surface of the solar cell 1 to receive incidence solar lights from any direction. The non-plane lens unit 2 is a transparent substrate 21 cut with indents on a surface of the non-plane lens unit 2. A sectional view of the indents are triangular plate lens 22. And the non-plane lens unit 2 is a Fresnel lens module having a dome-like shape or a plane-roof shape.

The diffusing zone 3 is deposed on the non-plane lens unit 2 to redistribute light source on the solar cell 1. The diffusion zone 3 is located in a light zone of the non-plane lens unit 2 where an energy focus is formed at center of the solar cell 1. The diffusion zone 3 is a diffusion plate 31 in the light zone of the non-plane lens unit 2. Thus, a novel solar light concentrator is obtained.

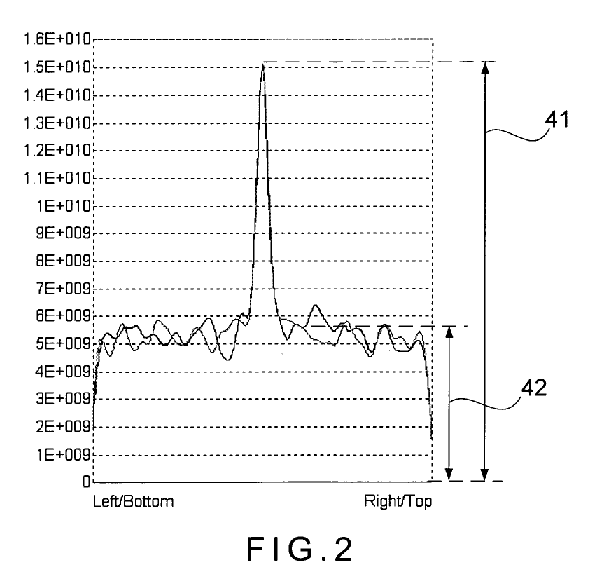

Please refer to FIG. 2, which is a view showing an energy amplitude distribution of solar beams on a solar cell. As shown in the figure, when applying the present invention, a size of a diffusion plate, recognized as an active area of a non-plane lens unit, is determined. When solar beams shine on the solar cell through the non-plane lens unit, a peak height 41 of an energy amplitude is three times higher than an average height 42 so that two third of the solar beams is redistributed evenly by the diffusion plate. The diffusion plate has a size obtained through steps of:

(a) obtaining a light zone for the solar beams shining on the solar cell through the non-plane lens unit

(b) subtracting the average amplitude of the solar cell from the maximum amplitude of the solar cell;

(c) dividing result of the step (b) by the maximum amplitude of the solar cell; and

(d) multiplying result from step (c) by the light zone from step (a). Therein, the size of the diffusion plate has an allowance of 20 percents more than and less than the size obtained above. And this area is the active area.

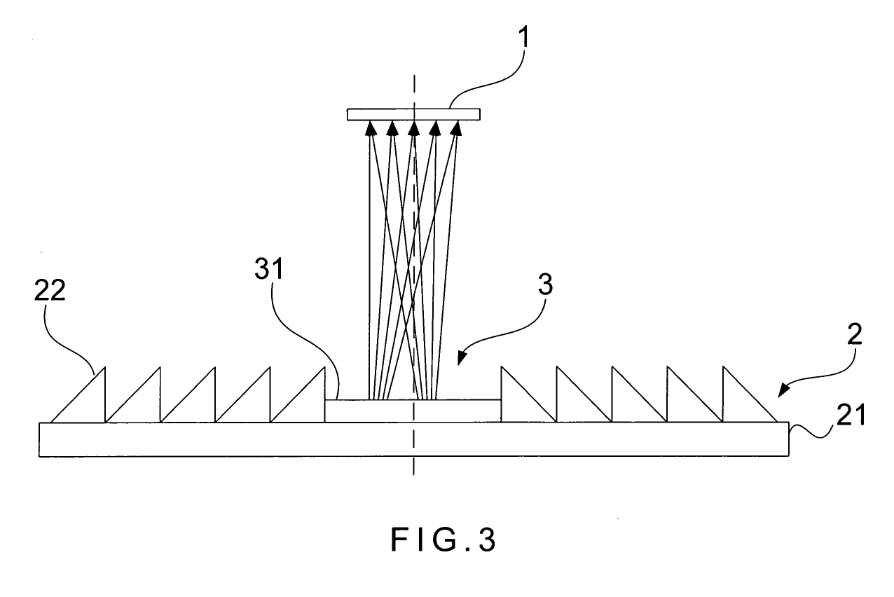

Please refer to FIG. 3, which is a view showing a state of use of the first preferred embodiment. As shown in the figure, when using the first preferred embodiment, solar beams are shone on a diffusion plate 31 of a diffusing zone 3. The solar beams are diffused by the diffusion plate 31 to be distributed evenly on a solar cell 1 so as to improve an efficiency of the solar cell 1.

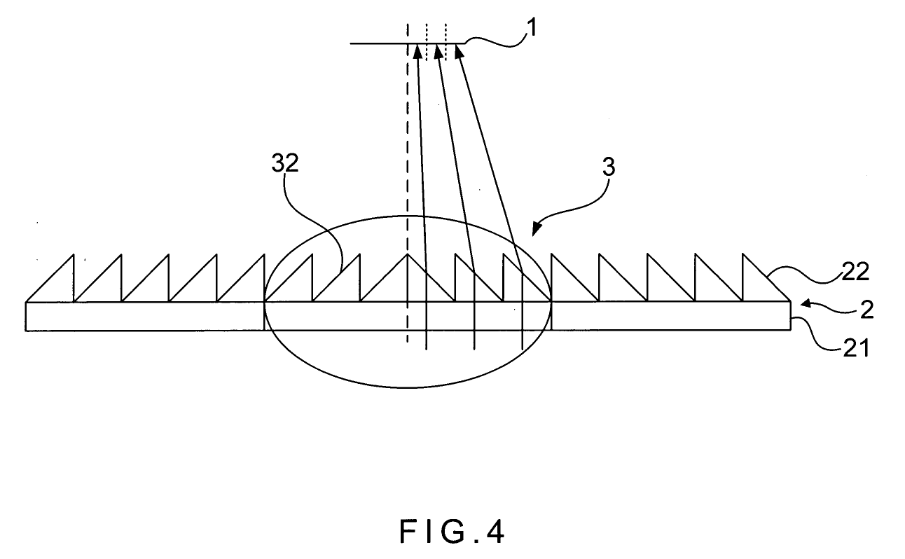

Please refer to FIG. 4, which is a view showing a state of use of a second preferred embodiment. As shown in the figure, a diffusing zone 3 comprises a plurality of concentric notches having various default angles at center of a non-plane lens unit 2. A side view of the notch shows a triangle and an overlook view of the notches are homocentric rings 32. And the solar beams are distributed evenly on the solar cell 1 with the default angles of the notches.

When using the second embodiment, solar beams are shone on the lens 32 and are diffused to be evenly distributed on the solar cell 1 for transforming light source of the solar beams into required energy.

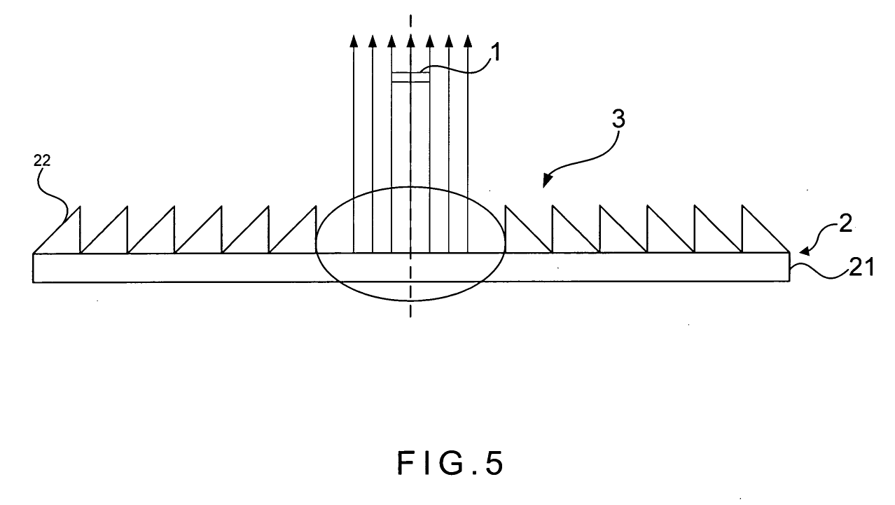

Please refer to FIG. 5, which is a view showing a state of use of a third preferred embodiment. As shown in the figure, a diffusing zone 3 is a space at center of the non-plane lens unit 2.

When using the third preferred embodiment, solar beams are not refracted before reaching a solar cell 1 through a diffusing zone 3 and then the solar cell 1 evenly receives the solar beams for transforming light source of the solar beams into required energy.

To sum up, the present invention is a solar light concentrator, where an even distribution of solar beams is obtained by using a diffusion plate to cure energy focus at center of a non-plane lens unit so as to evenly receive energy of the solar beams by a whole solar cell.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A solar light concentrator, comprising:
a solar cell, said solar cell collecting solar beam energy;
a non-plane lens unit, said non-plane lens unit being deposed on a surface of said solar cell to receive incidence solar light from any direction; and
a diffusing zone, said diffusing zone being deposed in an active area of said non-plane lens unit to have solar beams of sun light shone on said non-plane lens unit diffuse throughout said solar cell.

2. The solar light concentrator according to claim 1,
wherein said non-plane lens unit comprises a transparent substrate and a plurality of concentric notches at various default angles.

3. The solar light concentrator according to claim 1,
wherein said non-plane lens unit is a Fresnel lens module.

4. The solar light concentrator according to claim 1,
wherein said non-plane lens unit has a dome-like shape.

5. The solar light concentrator according to claim 1,
wherein said non-plane lens unit has a plane-roof shape.

6. The solar light concentrator according to claim 1,
wherein a size of said diffusing zone is obtained through steps of:
(a) obtaining a light zone for solar beams shining on said solar cell through said non-plane lens unit;
(b) subtracting an average amplitude in said solar cell from a maximum amplitude in said solar cell;
(c) dividing result of said step (b) by said maximum amplitude in said solar cell; and
(d) multiplying result from step (c) by said light zone from step (a); and
wherein said size of said diffusion plate has an allowance of 20 percents more than and 20 percents less than a size obtained through step (a) to step (d).

7. The solar light concentrator according to claim 1,
wherein said diffusing zone is a diffusion plate.

8. The solar light concentrator according to claim 1,
wherein said diffusing zone is a plurality of triangular plate lenses at various default angles to diffuse said solar beams throughout said solar cell.
